(19) United States
(12) Patent Application Publication
(10) Pub. No.: US 2024/0379642 A1
(43) Pub. Date: Nov. 14, 2024

(54) TRANSPARENT LIGHT EMITTING PACKAGE AND MANUFACTURING METHOD THEREOF

(71) Applicant: Global Technologies Co., LTD, Hwaseong-si Gyeonggi-do (KR)

(72) Inventors: Min Seon KIM, Hwaseong-si Gyeonggi-do (KR); Yong Geun KIM, Suwon-si Gyeonggi-do (KR)

(73) Assignee: Global Technologies Co., LTD, Hwaseong-si Gyeonggi-do (KR)

(21) Appl. No.: 18/659,944

(22) Filed: May 9, 2024

(30) Foreign Application Priority Data
May 10, 2023 (KR) 10-2023-0060592

(51) Int. Cl. H01L 25/16; H01L 21/48; H01L 23/538

(52) U.S. Cl. CPC H01L 25/167; H01L 21/4857; H01L 23/5383

(57) ABSTRACT

The present disclosure relates to a transparent light emitting package and manufacturing method thereof in which a light emitting device and a driving device can be packaged to form one pixel, and may include a substrate; a first wiring layer formed on a first surface of the substrate; at least one light emitting device mounted on a portion of the first wiring layer; at least one driving device mounted on other portion of the first wiring layer driving the light emitting device; a second wiring layer formed on a second surface of the substrate; and a penetrating electrode penetrating at least a portion of the substrate such that the first wiring layer and the second wiring layer are electrically connected.

### CROSS-REFERENCE TO RELATED APPLICATION(S)

This application is based on and claims priority under 35 U.S.C. § 119(a) to Korean Patent Application No. 10-2023-0060592, filed on May 10, 2023, in the Korean Intellectual Property Office, the entire contents of which application is incorporated herein by reference.

### TECHNICAL FIELD

The present disclosure relates to a transparent light emitting package and manufacturing method thereof, and more specifically to the transparent light emitting package and manufacturing method thereof in which a light emitting device and a driving device can be packaged to form one pixel.

### BACKGROUND

Generally in a light emitting device package, a light emitting device is mounted on a substrate with a terminal formed on the lower surface, and a protection member protecting the light emitting device is molded.

These conventional light emitting device packages may include a red light emitting device package, a green light emitting device package, and a blue light emitting device package, with a total of three packages combined to form one pixel.

Further, a conventional transparent display apparatus is an apparatus in which such conventional packages are mounted on a transparent substrate. In the conventional transparent display apparatus, additional driving devices, such as a separate large driver IC, may be mounted on the border to control the pixels composed of these packages.

However, such conventional light emitting device packages and the transparent light emitting package in which they are mounted require at least three packages to form one pixel.

Accordingly, the minimum mounting areas of the packages increased, making it difficult to increase the resolution.

Further, since a driving device such as a large driver IC controlling multiple packages was required, wiring became complicated.

Furthermore, since space for the driving device such as bezel space to be installed was needed, display enlargement was limited.

Additionally, transparency and heat resistance were reduced.

### SUMMARY

According to an aspect of the present disclosure, a transparent light emitting package may include a substrate; a first wiring layer formed on a first surface of the substrate; at least one light emitting device mounted on a portion of the first wiring layer; at least one driving device mounted on other portion of the first wiring layer driving the light emitting device; a second wiring layer formed on a second surface of the substrate; and a penetrating electrode penetrating at least a portion of the substrate such that the first wiring layer and the second wiring layer are electrically connected.

Meanwhile, according to an aspect of the present disclosure, a manufacturing method of the transparent light emitting package may include a step (a) wherein a first wiring layer is formed on a first substrate layer formed of a transparent or a light transmissive material; a step (b) wherein a second wiring layer is formed on a second substrate layer formed of a transparent or a light transmissive material; a step (c) wherein the first substrate layer is disposed so that the first wiring layer faces upper side, the second substrate layer is disposed so that the second wiring layer faces lower side, and the first substrate layer and the second substrate layer are thermocompressed with a laminating member disposed between them to form a substrate; a step (d) wherein a via hole is formed on the substrate, and a penetrating electrode is formed on the via hole; a step (e) wherein the substrate is etched so that unnecessary portions of the first wiring layer and the second wiring layer can be removed; a step (f) wherein at least one light emitting device and at least one driving device for driving the light emitting device are mounted on the first wiring layer; a step (g) wherein a package protection member is formed on the substrate to protect the light emitting device and the driving device according to necessity; and a step (h) wherein a unit package is singulated (individualized) by cutting the penetrating electrode or the substrate along a cutting line formed on the penetrating electrode or the substrate.

### BRIEF DESCRIPTION OF DRAWINGS

FIG. 1 is a perspective view of a transparent light emitting package according to some embodiments of the present disclosure.

FIG. 2 is an exploded perspective view of components of the transparent light emitting package of FIG. 1.

FIG. 3 is a top plan view of the transparent light emitting package of FIG. 1.

FIG. 4 is a bottom view of the transparent light emitting package of FIG. 1.

FIG. 5 is a cross-sectional view of the transparent light emitting package of FIG. 1.

FIGS. 6 to 15 are cross-sectional views sequentially illustrating manufacturing processes of the transparent light emitting package of FIG. 1.

FIG. 16 is a flowchart illustrating a manufacturing method of the transparent light emitting package according to some embodiments of the present disclosure.

FIG. 17 is a perspective view of a transparent light emitting package according to some other embodiments of the present disclosure.

FIG. 18 is a top plan view showing a first wiring layer and a second wiring layer of the transparent light emitting package of FIG. 17.

FIG. 19 is a cross-sectional view illustrating a manufacturing process of the transparent light emitting package of FIG. 17.

### DETAILED DESCRIPTION OF EXEMPLARY EMBODIMENTS

Hereinafter, the present disclosure will be described in detail by explaining embodiments of the invention with reference to the attached drawings.

Various embodiments of the present disclosure may be embodied in many different forms and should not be construed as being limited to the example embodiments set forth herein. Rather, these embodiments of the disclosure are provided so that this disclosure will be thorough and complete and will convey inventive concepts of the disclosure to those skilled in the art. In the drawings, the thicknesses or sizes of layers are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

Although the terms first, second, etc. are used herein to describe various elements, components, regions, layers and/or portions, these elements, components, regions, layers and/or portions should not be limited to the terms. These terms are only used to distinguish one member, element, region, layer, and/or section from another. Thus, a first member, component, region, layer or portion described below may refer to a second member, component, region, layer or portion without departing from the teachings of the present invention.

The present disclosure is intended to solve various problems including the above problems aims to provide the transparent light emitting package and manufacturing method thereof, wherein the overall thickness of the product can be made ultra-thin by individually mounting the R, G, and B LED chips and the driver IC that controls them in one transparent light emitting package, and the manufacturing process thereof is simplified, allowing the process and quality control to be easily performed.

Further, the present disclosure aims to provide the transparent light emitting package and manufacturing method thereof, wherein the unit cost of the product can be greatly reduced by forming the substrate by laminating copper foil-formed films to form a double-sided pattern.

Further, the present disclosure aims to provide the transparent light emitting package and manufacturing method thereof, wherein individual control of the LEDs can be made easy, greatly improving the expressiveness of images.

Further, the present disclosure aims to provide the transparent light emitting package and manufacturing method thereof, wherein by minimizing the driver IC and dispersing it into each light emitting device package, concentrated heat generation can be prevented.

Further, the present disclosure aims to provide the transparent light emitting package and manufacturing method thereof, wherein transparency and heat resistance can be improved greatly. However, these problems are exemplary and do not limit the scope of the present disclosure.

According to an embodiment of the present disclosure having the above configuration, the overall thickness of the product can be made ultra-thin by individually mounting the R, G, and B LED chips and the driver IC that controls them in one transparent light emitting package, and the manufacturing process thereof is simplified, allowing the process and quality control to be easily performed.

Further, the unit cost of the product can be greatly reduced by forming the substrate by laminating copper foil-formed films to form a double-sided pattern.

Further, individual control of the LEDs can be made easy, greatly improving the expressiveness of images.

Further, by minimizing the driver IC and dispersing it into each light emitting device package, concentrated heat generation can be prevented.

Further, transparency and heat resistance can be improved greatly. However, these problems are exemplary and do not limit the scope of the present disclosure.

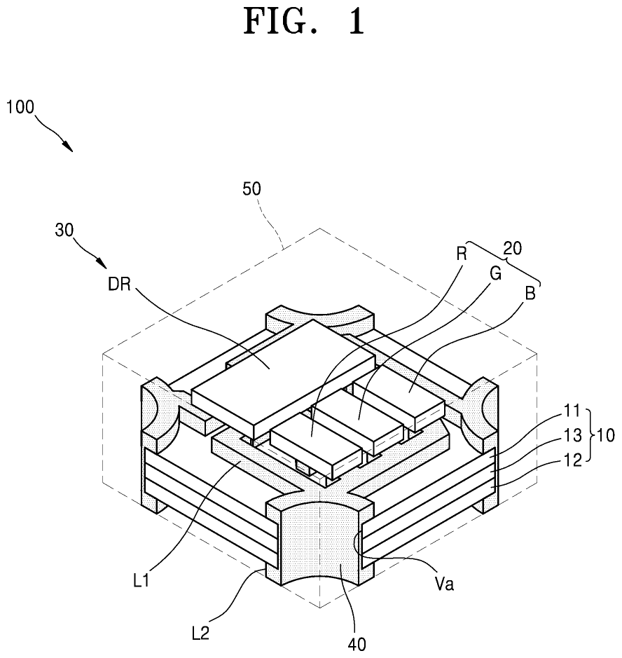

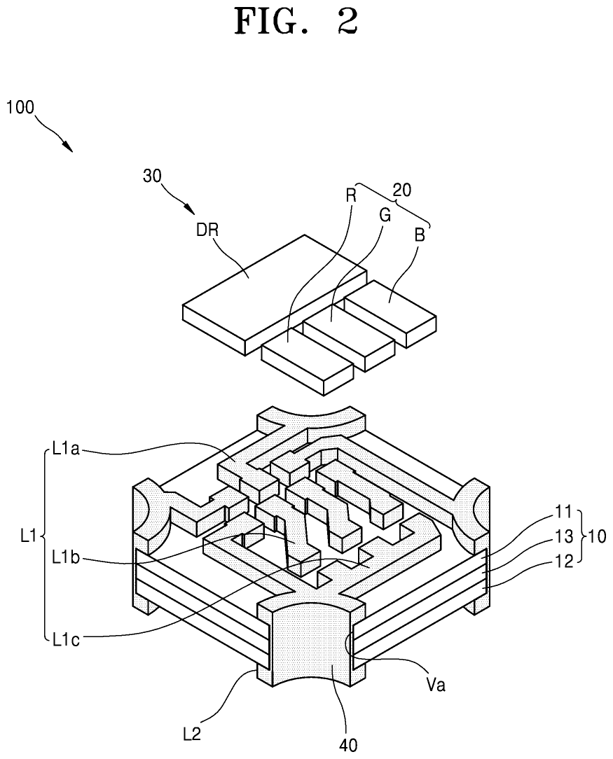

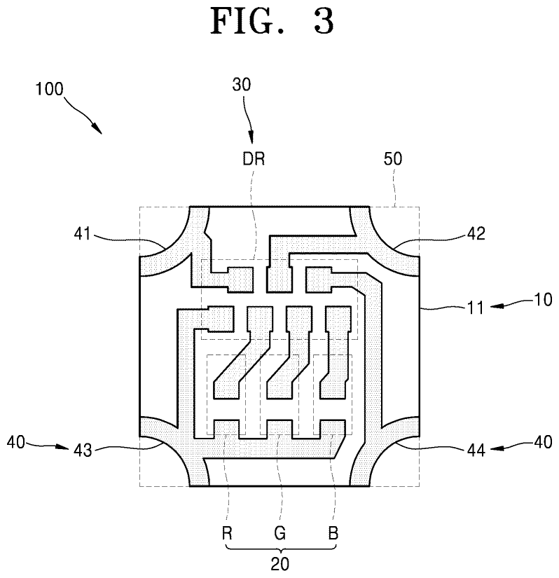

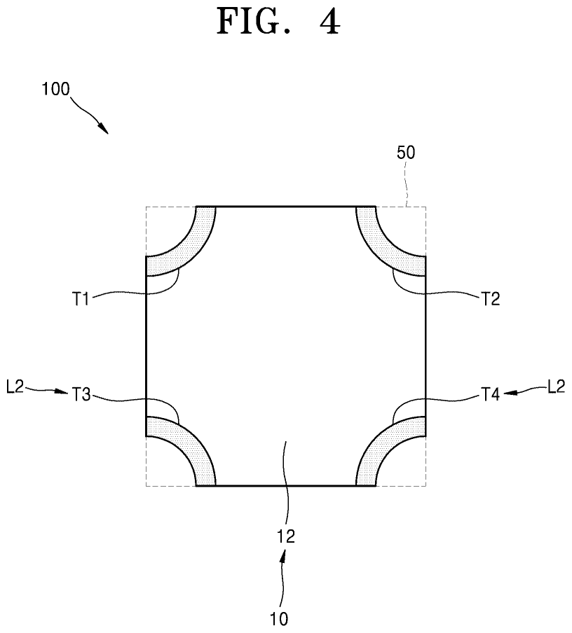

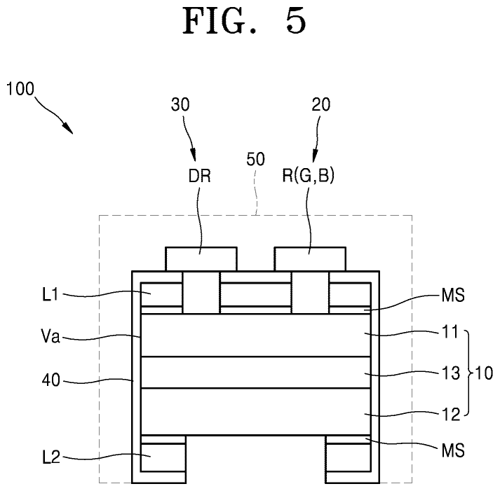

FIG. 1 is a perspective view of a transparent light emitting package according to some embodiments of the present disclosure, FIG. 2 is an exploded perspective view of components of the transparent light emitting package of FIG. 1, FIG. 3 is a top plan view of the transparent light emitting package of FIG. 1, FIG. 4 is a bottom view of the transparent light emitting package of FIG. 1, and FIG. 5 is a cross-sectional view of the transparent light emitting package of FIG. 1.

First, as shown in FIGS. 1 to 5, the transparent light emitting package 100 according to some embodiments of the present disclosure may extensively include a substrate 10, a first wiring layer L1, a light emitting device 20, a driving device 30, a second wiring layer L2, a penetrating electrode 40, and a package protection member 50.

The substrate 10, wherein the first wiring layer L1 is formed on the upper surface and the second wiring layer L2 is formed on the lower surface, may include a film layer at least partially made of a highly light transmissive polyimide material. In addition, the substrate 10 may be made of insulating materials such as polyimide, polypropene, propylene ethylene, polyethylene, rubber, urethane, polyolefin, polyester, polypropylene, and polyethylene terephthalate.

The substrate 10 may include a first substrate layer 11 formed of a transparent or a light transmissive material wherein a first wiring layer L1 is formed on the upper surface, a second substrate layer 12 formed of a transparent or a light transmissive material wherein a second wiring layer L2 is formed on the lower surface, and a laminating member 13 formed of a transparent or a light transmissive material, formed between the first substrate layer 11 and the second substrate layer 12 so that the laminating member 13 can adhere to the first substrate layer 11 and the second substrate layer 12.

The laminating member 13 is a combining member and may be a type of adhesive layer that can be melted and adhered at a high temperature and high pressure.

Therefore, the substrate 10 may be formed by placing first substrate layer 11 on the upper side and second substrate layer 12 on the lower side with the laminating member 13 in between and thermocompressing at high temperature and high pressure. However, the manufacturing method of the substrate 10 is not limited to the laminating member 13 or the thermocompression method, and various types of substrate manufacturing methods can be applied.

The first wiring layer L1 may be a thin film layer made of a conductive material such as copper, aluminum, gold, silver, or platinum formed on a first surface (upper surface in the drawing) of the substrate 10.

The second wiring layer L2 may be a thin film layer made of a conductive material such as copper, aluminum, gold, silver, or platinum formed on a second surface (lower surface in the drawing) of the substrate 10.

The first wiring layer L1 and the second wiring layer L2 may be formed by forming a metal seed layer entirely or in a pattern on the surfaces of the first substrate layer 11 and second substrate layer 12, respectively, and then using a metal layer forming process such as sputtering or plating.

However, the first wiring layer L1 and the second wiring layer L2 may be formed using a variety of processes, such as a printed circuit method or an adhesive method, in addition to the metal layer forming process using the metal seed layer.

As shown in FIG. 2, the first wiring layer L1 may include a driving device side wiring L1a formed to extend from the upper end of the penetrating electrode 40 to any one of the terminals of the driving device 30, a middle wiring L1b formed to extend from any one of the terminals of the driving device 30 to any one of the pads of the light emitting device 20, and a light emitting device side wiring L1c formed to extend from other pads of the middle wiring L1b and the light emitting device 20 to the upper end of another penetrating electrode 40.

Therefore, driving power applied through the penetrating electrode 40 or a control signal may be applied to the light emitting devices 20 and the driving device 30 using the driving device side wiring L1a, middle wiring L1b, and light emitting device side wiring L1c.

As shown in FIG. 4, the second wiring layer L2 may include a (2-1)th terminal T1 formed on a first corner portion of the substrate 10, connected to the driving device side wiring L1a through a corner penetrating electrode 41, a (2-2)th terminal T2 formed on a second corner portion of the substrate 10, connected to the other driving device side wiring L1a through a corner penetrating electrode 42, a (2-3)th terminal T3 formed on a third corner portion of the substrate 10, connected to another driving device side wiring L1a through a corner penetrating electrode 43, and a (2-4)th terminal T4 formed on a fourth corner portion of the substrate 10, connected to another driving device side wiring L1a or the light emitting device side wiring L1c through a corner penetrating electrode 44.

Therefore, when the driving power and the control signal are applied from the outside, they are applied to the penetrating electrode 40 through the (2-1)th terminal T1, the (2-2)th terminal T2, the (2-3)th terminal T3, and the (2-4)th terminal T4, and they are again applied to the light emitting devices 20 and the driving device 30 through the penetrating electrode 40 to the driving device side wiring L1a, middle wiring L1b, and light emitting device side wiring L1c.

In addition, the first wiring layer L1 and the second wiring layer L2 may be patterned on the first substrate layer 11 and second substrate layer 12, respectively, by plating, transferring, applying, sputtering, etching, developing, printing, and the like.

The light emitting device 20 is at least one regular LED, micro LED, or mini LED mounted on a portion of the first wiring layer L1, and may include a red LED chip R, a green LED chip G, and a blue LED chip B to form one pixel.

The light emitting device 20 may be applied with a flip chip form LED (Light Emitting Diode) in which a first pad and a second pad are formed on the lower surface.

The light emitting device 20 may be applied with all of the red, green, and blue LEDs in the form of a flip chip, but is not necessarily limited thereto, and LEDs that are non-flip form inorganic light-emitting chips of various colors with a pad formed on the upper surface may also be applied. Such light emitting device 20 can be applied with all types of LEDs, such as mini LEDs or micro LEDs, as well as general LEDs.

That is, although not shown, a light emitting device in which a bonding wire is applied to the terminal, or in which a bonding wire is partially applied only to the first or second terminal, a horizontal light emitting device, a vertical light emitting device, and the like can be applied, but for miniaturization and ultra-thinness of a product, a flip chip form may be desirable.

The light emitting device 20 can be prepared by epitaxially growing a nitride semiconductor such as InN, AlN, InGaN, AlGaN, InGaAlN, or InGaAlN on a sapphire growth substrate or a silicon carbide substrate, for example, by using a vapor deposition method such as a MOCVD method. In addition to the nitride semiconductor, the light emitting device 20 may also be formed using a semiconductor such as ZnO, ZnS, ZnSe, SiC, GaP, GaAlAs, and AlInGaP. These semiconductors may utilize a laminate formed in the order of an n-type semiconductor layer, a light emitting layer, and a p-type semiconductor layer. The light emitting layer (active layer) may utilize a laminated semiconductor with a multi-quantum-well structure, a single quantum-well structure, or a double hetero-structure. Furthermore, the light emitting device 20 may be selected with an arbitrary wavelength depending on the usage, such as display or lighting.

Here, an insulating, a conductive, or a semiconductor substrate may be used as the growth substrate according to necessity. For example, the growth substrate may be sapphire, SiC, Si, MgAl₂O₄, MgO, LiAlO₂, LiGaO₂, or GaN. For epigrowth of GaN materials, a GaN substrate which is a substrate of a same type, can be applied.

The driving device 30 is a semiconductor device mounted on other part of the first wiring layer L1 which drives the light emitting device 20, and may be a driver IC DR wherein a terminal is formed by including any one or more of a power terminal, a drive voltage terminal, a control terminal, a feedback terminal, a brightness adjustment terminal, a light amount calibration terminal, a dummy terminal, or the combinations thereof on one side, in order to apply control signals to each of the red LED chip R, the green LED chip G, and the blue LED chip B.

The driving device 30 includes at least one drive circuit which functions as the driver IC, and may have various forms of circuits to supply power, control the drive voltage, process feedback signals, control the drive brightness of the light emitting device 20, or calibrate the light amount of the light emitting device 20 to match the reference light amount of other light emitting devices.

The driving device 30 may include a semiconductor substrate formed using an integrated circuit process on a semiconductor wafer such as a silicon wafer, wherein the semiconductor substrate may be formed in multiple layers of a semiconductor material, and electrical connections of the drive circuits formed in each layer may utilize an RDL (redistribution) metal layer.

The driving device 30 may have at least one terminal formed on one side of the semiconductor substrate for receiving power signals or input/output signals for the drive circuit to input or output signals.

These terminals can be applied with highly electrically conductive materials such as Cu, Ni, Ag, Au, and others, and can be applied in various forms such as solders, bumps, or pads.

In a more specific example, the terminal may be selected from any one or more of the power terminals, the drive voltage terminal, the control terminal, the feedback terminal, the brightness adjustment terminal, the light amount calibration terminal, the dummy terminal, and combinations thereof.

The penetrating electrode 40 may be a type of side electrode formed on a side of the substrate 10 that penetrates at least a portion of the substrate 10 such that the first wiring layer L1 and the second wiring layer L2 are electrically connected.

The penetrating electrode 40 as shown in FIG. 3, may be at least a portion (a quarter portion in the drawings) of corner penetrating electrodes 41, 42, 43, and 44 formed by plating or the like a conductive material on the via holes Va formed on the four corner portions of the substrate 10 so that it can be cut into quarters during an individualization process. However, the penetrating electrodes are not necessarily limited to the drawings and may be cut in half, uncut, or formed inside of the substrate 10.

The package protection member 50 is a type of sealing member that protects the light emitting device 20 and the driving device 30, wherein the package protection member 50 may include at least one of a light transmitting molding member formed of a light transmissive material including silicone or epoxy, a lens member, a light conversion member including a fluorescent material or a quantum dot, a color filter member, an optical system, a reflective wall member, or combinations thereof.

The package protection member 50 may be the light transmissive material including at least silicone or epoxy, wherein the light transmitting molding member formed by casting can be applied.

However, the package protection member 50 is not limited to the light transmitting molding member, and may also be applied with the light conversion member including a fluorescent material or the quantum dot, the color filter members, the optical system, the reflective wall member, and the like.

Here, the fluorescent material must basically conform to stoichiometry, and each element can be substituted for any other elements in each family on the periodic table. For example, Sr can be substituted with Ba, Ca, Mg, or the like of the alkaline earth group (II), Y can be substituted with Tb, Lu, Sc, Gd, or the like of the lanthanide group. Active agents such as Eu can be substituted with Ce, Tb, Pr, Er, Yb, or the like depending on the desired energy level, and the active agent alone, or co-active agents can be applied additionally to modify properties.

Further, the quantum dot may be a nanometer-sized particle that can have optical properties arising from quantum confinement, and may be formed including, for example, one or more of the following: a Group IV element, a Group II-VI compound, a Group II-V compound, a Group III-VI compound, a Group III-V compound, a Group IV-VI compound, a Group I-III-VI compound, a Group II-IV-VI compound, and a Group II-IV-V compound.

The quantum dot may be formed including one or more of ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AlP, AlSb, TIN, TIP, TlAs, TlSb, PbO, PbS, PbSe, PbTe, Ge, or Si.

In addition, the quantum dot can be composed of a core (3 to 10 nm) such as CdSe, InP, or the like, a shell (0.5 to 2 nm) such as ZnS, ZnSe, or the like, and a ligand structure for stabilization of the core and the shell, and may have optical properties that can implement various colors depending on the size.

In addition, the quantum dot may include a monomer that can be included in a physical structure or other forms and polymerized into a desired physical structure, such as a film.

In a more specific example, in addition to a sheet form, the quantum dot can be injected and cured in a paste form along with various binders, formed into other liquid states, or formed into various fluid states, such as a gel or a gel state.

Further, the light conversion member may include two or more phosphor and quantum dot materials having different light emission wavelengths, and the phosphors and quantum dots may be used as a mixture.

Thus, the operation process of the present disclosure is described as follows: When the drive power and control signals are applied from the outside, they can be applied to the penetrating electrode 40 through the (2-1)th terminal T1, the (2-2)th terminal T2, the (2-3)th terminal T3, and the (2-2)th terminal (T4), and they are again applied to the driving device 30 through the penetrating electrode 40 using the driving device side wiring L1a and the middle wiring L1b.

The driving device 30 then applies the drive power through the light emitting device side wiring L1c by applying the control signal to the red LED chip R, the green LED chip G, and the blue LED chip B according to the control signal to supply power in RGB pixel basis,

The driving device 30 can also apply the drive voltage and control it, or adjusts brightness or light amount using a feedback function to express colors or contrasts finely and precisely on an individual pixel basis.

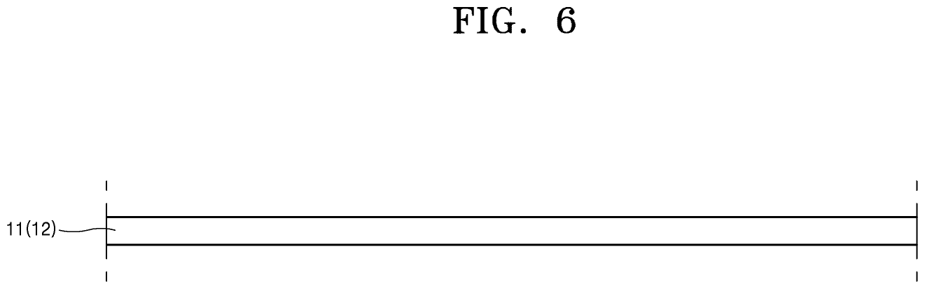

FIGS. 6 to 15 are cross-sectional views sequentially illustrating manufacturing processes of the transparent light emitting package 100 of FIG. 1.

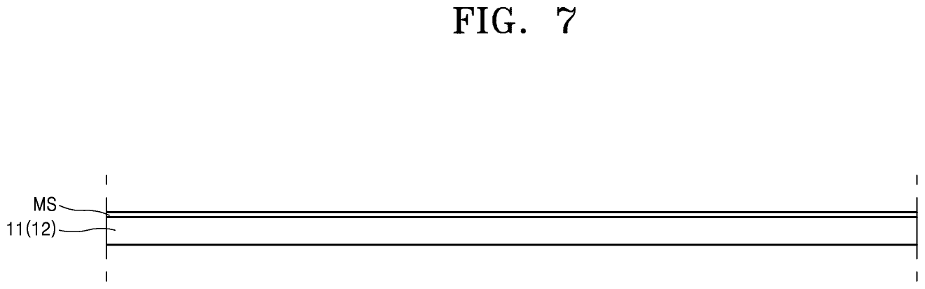

As shown in FIGS. 6 to 15, the manufacturing process of the transparent light emitting package 100 of FIG. 1 is as follows: First, as shown in FIG. 6, the first substrate layer 11 formed of a transparent or light transmissive material is prepared, and as shown in FIG. 7, the metal seed layer MS can be formed on the first substrate layer 11 through a process such as sputtering.

At this time, the metal sheet layer MS can be formed over the entire surface of the first substrate layer 11, or can be formed only partially.

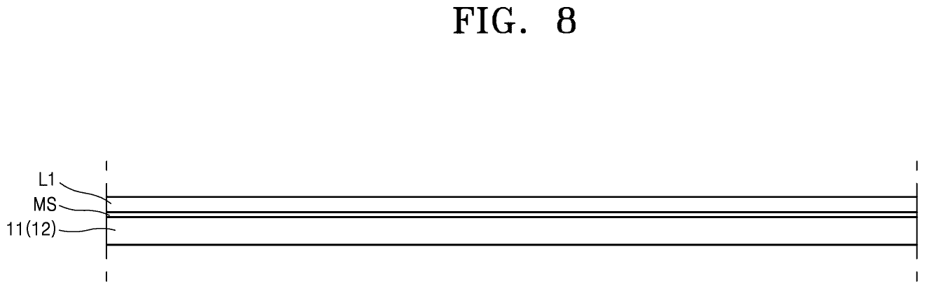

Subsequently, as shown in FIG. 8, the second wiring layer (L2) can be formed on the metal sheet layer MS by plating or other methods.

Meanwhile, although not shown, the second wiring layer L2 can be formed using the metal seed layer MS on the second substrate layer 12 formed of a transparent or light transmissive material through the same process as in FIGS. 6 to 8.

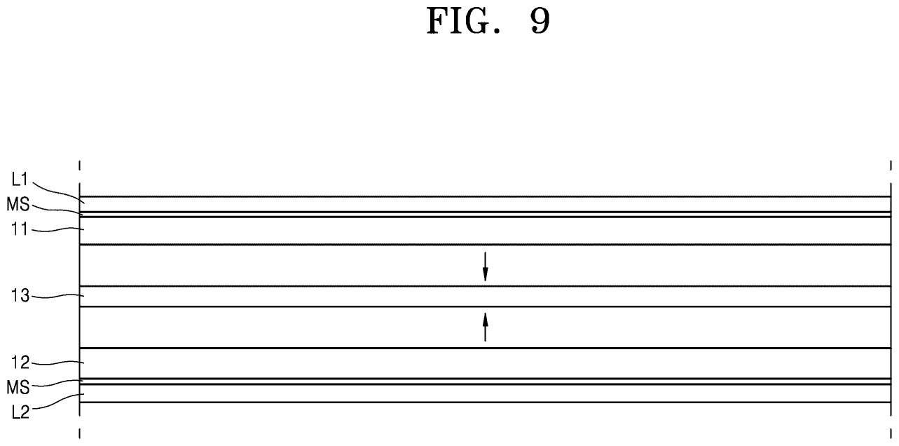

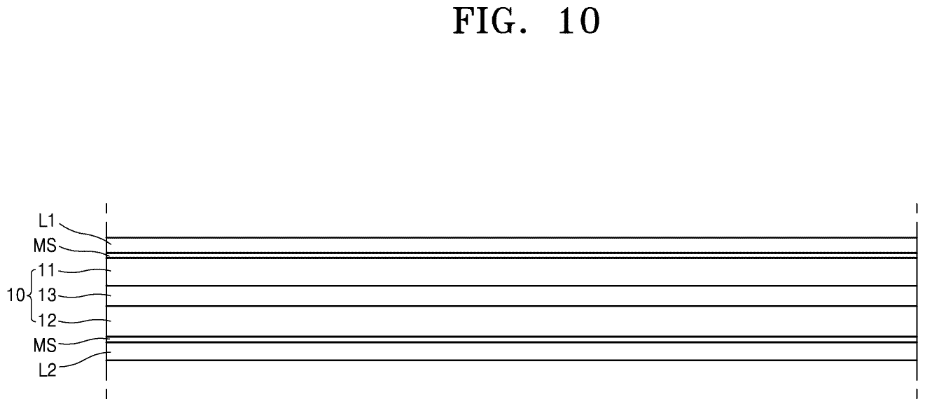

Subsequently, as shown in FIG. 9, the first substrate layer 11 is disposed so that the first wiring layer L1 faces the upper side, the second substrate layer 12 is disposed so that the second wiring layer L2 faces the lower side, the laminating member 13 disposed between the first substrate layer 11 and the second substrate layer 12, and as shown in FIG. 10, they can be thermocompressed to form the substrate 10.

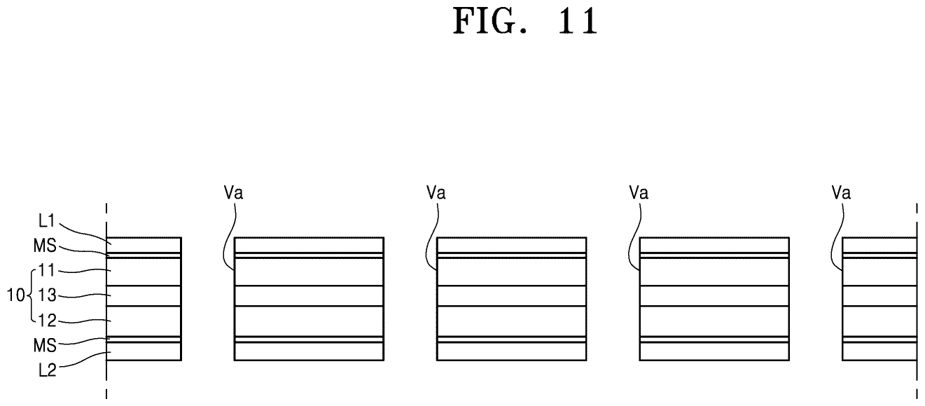

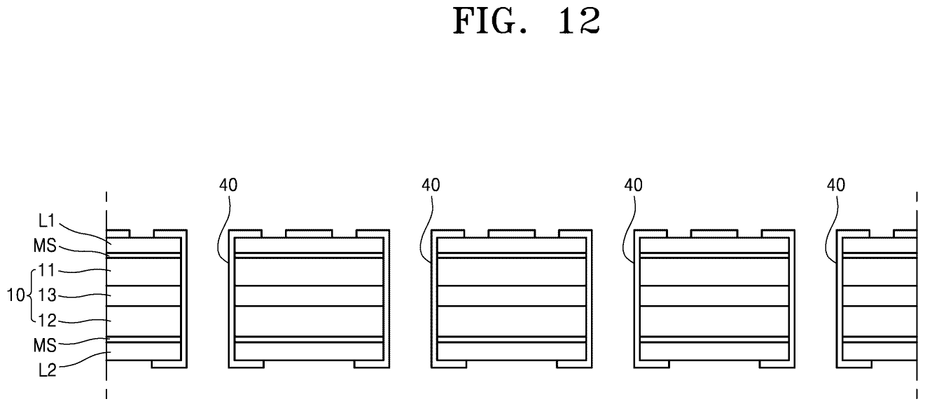

Subsequently, as shown in FIG. 11, the via hole Va is formed on the substrate 10, and as shown in FIG. 12, the penetrating electrode 40 can be formed on the via hole Va by a plating or circuit printing method.

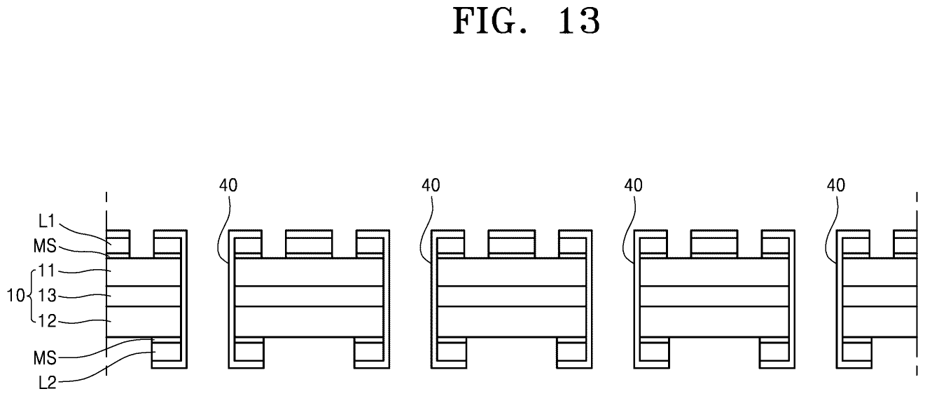

Subsequently, as shown in FIG. 13, the first wiring layer L1 and the second wiring layer L2 can be completed by etching the substrate 10 so that unnecessary parts can be removed from the first wiring layer L1 and the second wiring layer L2.

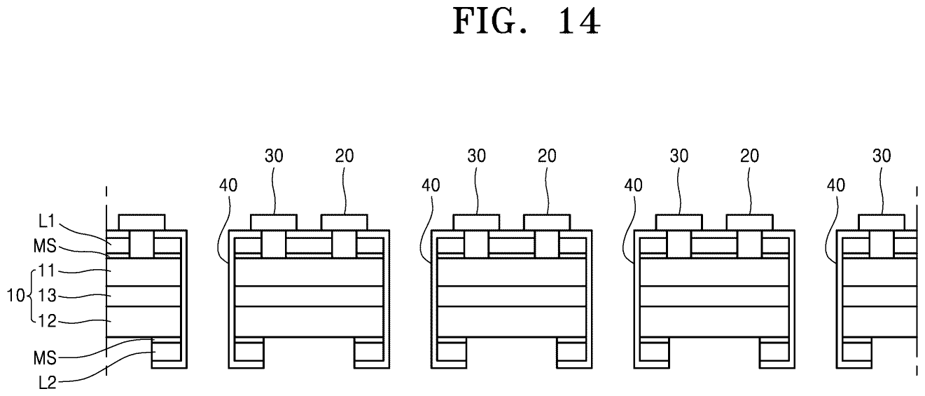

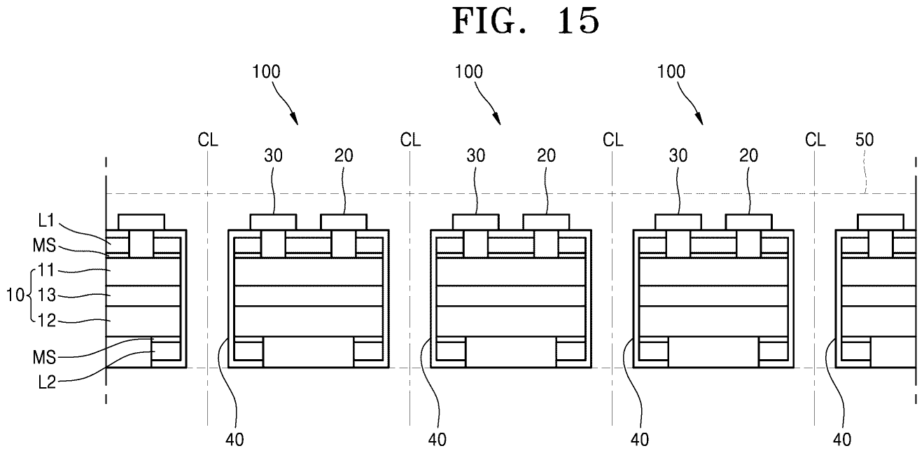

Subsequently, as shown in FIG. 14, at least one light emitting device 20 and at least one driving device 30 that drives the light emitting device 20 can be mounted on the first wiring layer L1, and as shown in FIG. 15, the package protection member 50 can be formed on the substrate 10 to protect the light emitting device 20 and the driving device 30 according to necessity.

Subsequently, as shown in FIG. 15, a unit package can be singulated (individualized) by cutting the penetrating electrode 40 or the substrate 10 along the cutting line CL formed on the penetrating electrode 40 or the substrate 10.

Therefore, according to the present disclosure, the overall thickness of the product can be made ultra-thin by individually mounting the R, G, and B LED chips and the driver IC that controls them in one transparent light emitting package, and the manufacturing process thereof is simplified, allowing the process and quality control to be easily performed.

Further, the unit cost of the product can be greatly reduced by forming the substrate by laminating copper foil-formed films to form a double-sided pattern.

Further, individual control of the LEDs can be made easy, greatly improving the expressiveness of images.

Further, by minimizing the driver IC and dispersing it into each light emitting device package, concentrated heat generation can be prevented.

Further, transparency and heat resistance can be improved greatly.

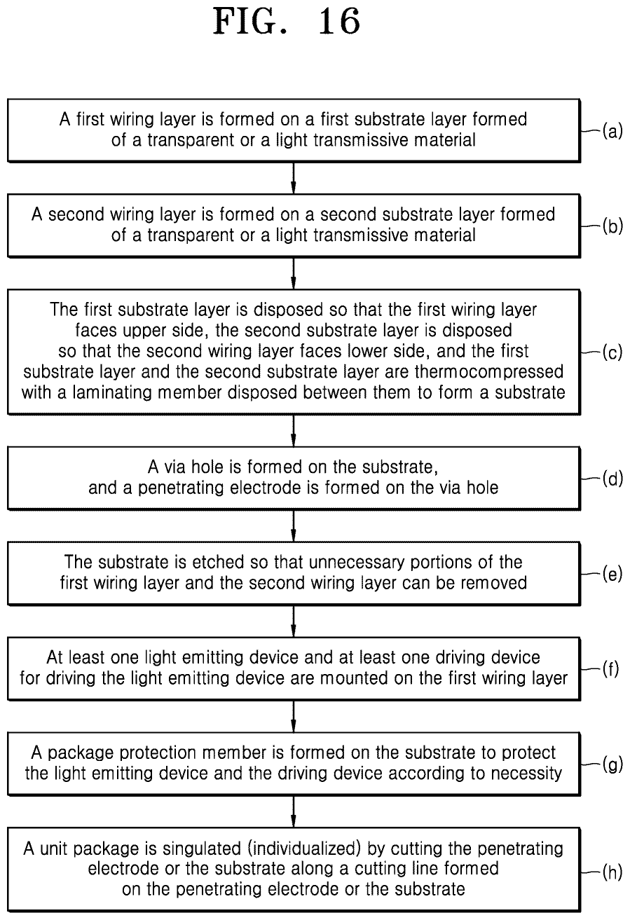

FIG. 16 is a flowchart illustrating the manufacturing method of the transparent light emitting package 100 according to some embodiments of the present disclosure.

As shown in FIGS. 1 to 16, a manufacturing method of the transparent light emitting package 100 according to some embodiments of the present disclosure may include a step (a) wherein the first wiring layer L1 is formed on the first substrate layer 11 formed of a transparent or a light transmissive material; a step (b) wherein the second wiring layer L2 is formed on a second substrate layer 12 formed of a transparent or a light transmissive material; a step (c) wherein the first substrate layer 11 is disposed so that the first wiring layer L1 faces upper side, the second substrate layer 12 is disposed so that the second wiring layer L2 faces lower side, and the first substrate layer 11 and the second substrate layer 12 are thermocompressed with a laminating member disposed between them to form the substrate 10; a step (d) wherein the via hole Va is formed on the substrate 10, and the penetrating electrode 40 is formed on the via hole Va; a step (e) wherein the substrate 10 is etched so that unnecessary portions of the first wiring layer L1 and the second wiring layer L2 can be removed; a step (f) wherein at least one light emitting device 20 and at least one driving device 30 for driving the light emitting device 20 are mounted on the first wiring layer L1; a step (g) wherein the package protection member 50 is formed on the substrate 10 to protect the light emitting device 20 and the driving device 30 according to necessity; and a step (h) wherein a unit package is singulated (individualized) by cutting the penetrating electrode 40 or the substrate 10 along the cutting line CL formed on the penetrating electrode 40 or the substrate 10.

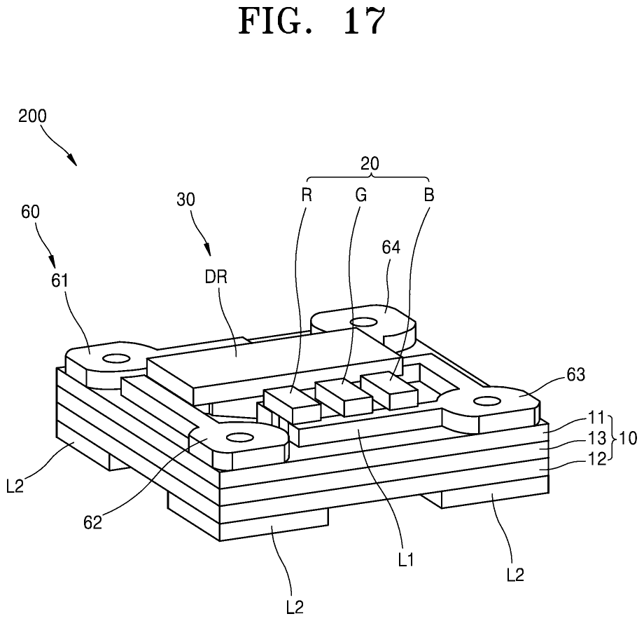

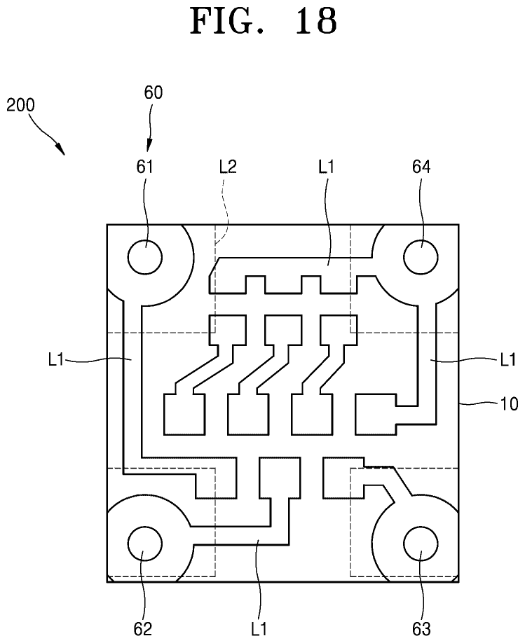

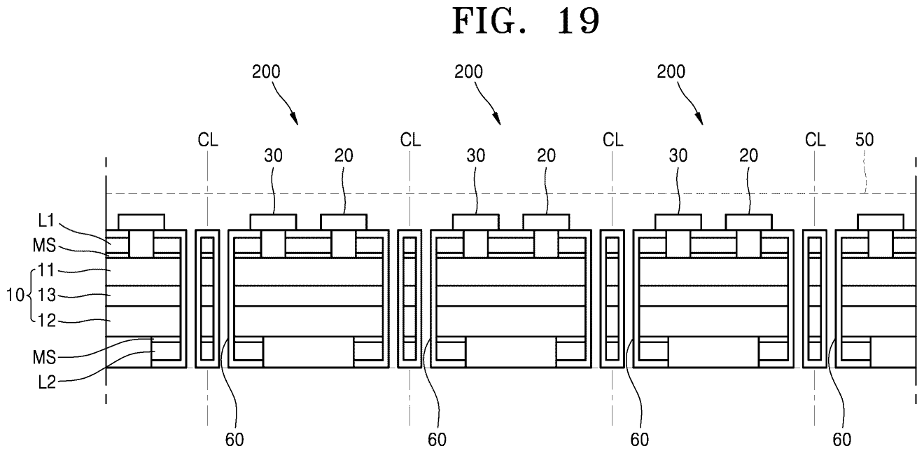

FIG. 17 is a perspective view of a transparent light emitting package 200 according to some other embodiments of the present disclosure, FIG. 18 is a top plan view showing a first wiring layer L1 and a second wiring layer L2 of the transparent light emitting package 200 of FIG. 17, and FIG. 19 is a cross-sectional view illustrating a manufacturing process of the transparent light emitting package 200 of FIG. 17.

As shown in FIGS. 17 and 18, the transparent light emitting package 200 according to some other embodiments of the present disclosure may be border penetrating electrodes 61, 62, 63, and 64 formed by plating a conductive material on via holes Va formed on four diagonal border portions of the substrate 10.

Accordingly, as shown in FIG. 19, a unit package can be singulated (individualized) by cutting the substrate 10 or the substrate along the cutting line CL formed between the penetrating electrodes and other neighboring penetrating electrodes.

Such penetrating electrodes is not necessarily limited to the drawings, and may be formed in a variety of shapes at a wide variety of positions.

The present disclosure has been described with reference to the embodiments illustrated in the drawings, but these embodiments are merely illustrative and it should be understood by a person with ordinary skill in the art that various modifications and equivalent embodiments can be made without departing from the scope of the present disclosure. Therefore, the true technical protective scope of the present disclosure must be determined based on the technical concept of the appended claims.

### REFERENCE SIGNS LIST

10: Substrate
11: First substrate layer
12: Second substrate layer
13: Laminating member
L1: First wiring layer
L1a: Driving device side wiring
L1b: Middle wiring
L1c: Light emitting device side wiring
L2: Second wiring layer
T1: (2-1)th terminal
T2: (2-2)th terminal
T3: (2-3)th terminal
T4: (2-4)th terminal
20: Light emitting device
R: Red LED chip
G: Green LED chip
B: Blue LED chip
30: Driving device
DR: driver IC
40: Penetrating electrode
41, 42, 43, 44: Corner penetrating electrodes
Va: Via hole
50: Package protection member
CL: Cutting line
60: Penetrating electrode
61, 62, 63, 64: Border penetrating electrodes
100, 200: Transparent light emitting package

What is claimed is:

1. A transparent light emitting package comprising:
a substrate;
a first wiring layer formed on a first surface of the substrate;
at least one light emitting device mounted on a portion of the first wiring layer;
at least one driving device mounted on other portion of the first wiring layer driving the light emitting device;
a second wiring layer formed on a second surface of the substrate; and
a penetrating electrode penetrating at least a portion of the substrate such that the first wiring layer and the second wiring layer are electrically connected.

2. The transparent light emitting package of claim 1,
wherein the substrate comprises
a first substrate layer formed of a transparent or a light transmissive material wherein the first wiring layer is formed on an upper surface;
a second substrate layer formed of a transparent or a light transmissive material wherein the second wiring layer is formed on a lower surface; and
a laminating member formed of a transparent or a light transmissive material, formed between the first substrate layer and the second substrate layer so that the laminating member can adhere to the first substrate layer and the second substrate layer.

3. The transparent light emitting package of claim 1,
wherein the penetrating electrode is at least a part of a corner penetrating electrode formed by plating a conductive material on via holes formed on four corners of the substrate.

4. The transparent light emitting package of claim 1,
wherein the light emitting device comprises
a red LED chip, a green LED chip, and a blue LED chip to form one pixel.

5. The transparent light emitting package of claim 4,
wherein the driving device is a driver IC wherein a terminal is formed by comprising any one or more of a power terminal, a drive voltage terminal, a control terminal, a feedback terminal, a brightness adjustment terminal, a light amount calibration terminal, a dummy terminal, or combinations thereof, to apply a control signal to the red LED chip, the green LED chip, and the blue LED chip.

6. The transparent light emitting package of claim 1,
wherein the first wiring layer comprises
a driving device side wiring formed to extend from an upper end of the penetrating electrode to any one of terminals of the driving device;
a middle wiring formed to extend from any one of the terminals of the driving device to any one of pads of the light emitting device; and
a light emitting device side wiring formed to extend from other pads of the light emitting device to an upper end of another penetrating electrode.

7. The transparent light emitting package of claim 6,
wherein the second wiring layer comprises
a (2-1)th terminal formed on a first corner portion of the substrate, connected to the driving device side wiring;
a (2-2)th terminal formed on a second corner portion of the substrate, connected to other driving device side wiring;
a (2-3)th terminal formed on a third corner portion of the substrate, connected to another driving device side wiring; and
a (2-4)th terminal formed on a fourth corner portion of the substrate, connected to another driving device side wiring or the light emitting device side wiring.

8. The transparent light emitting package of claim 1, further comprising
a package protection member protecting the light emitting device and the driving device.

9. The transparent light emitting package of claim 8,
wherein the package protection member comprises at least one of a light transmitting molding member formed of a light transmissive material comprising silicone or epoxy, a lens member, a light conversion member comprising a fluorescent material or quantum dots, a color filter member, an optical system, a reflective wall member, or a combination thereof.

10. The transparent light emitting package of claim 1,
wherein the penetrating electrode
is a border penetrating electrode formed by plating a conductive material on via holes formed on four diagonal border portions of the substrate.

11. A manufacturing method of a transparent light emitting package, comprising:
a step (a) wherein a first wiring layer is formed on a first substrate layer formed of a transparent or a light transmissive material;
a step (b) wherein a second wiring layer is formed on a second substrate layer formed of a transparent or a light transmissive material;
a step (c) wherein the first substrate layer is disposed so that the first wiring layer faces upper side, the second substrate layer is disposed so that the second wiring layer faces lower side, and the first substrate layer and the second substrate layer are thermocompressed with a laminating member disposed between them to form a substrate;
a step (d) wherein a via hole is formed on the substrate, and a penetrating electrode is formed on the via hole;
a step (e) wherein the substrate is etched so that unnecessary portions of the first wiring layer and the second wiring layer can be removed;
a step (f) wherein at least one light emitting device and at least one driving device for driving the light emitting device are mounted on the first wiring layer;
a step (g) wherein a package protection member is formed on the substrate to protect the light emitting device and the driving device according to necessity; and
a step (h) wherein a unit package is singulated (individualized) by cutting the penetrating electrode or the substrate along a cutting line formed on the penetrating electrode or the substrate.
